(19) United States
(12) Patent Application Publication
(10) Pub. No.: US 2025/0034704 A1
(43) Pub. Date: Jan. 30, 2025

(54) SUBSTRATE PROCESSING APPARATUS AND SUBSTRATE PROCESSING METHOD

(71) Applicant: EUGENE TECHNOLOGY CO., LTD., Yongin-s (KR)

(72) Inventors: In Soo SON, Hwaseong-si (KR); Chang Hun SHIN, Icheon-si (KR); Chan Yong PARK, Icheon-si (KR); Deog Hwan KIM, Yongin-si (KR); Jae Jun JUNG, Seoul (KR); Si Won RYU, Yongin-si (KR); Chang Min PARK, Seoul (KR); Jae Sun KIM, Seoul (KR); Ki Hoon KIM, Suwon-si (KR)

(21) Appl. No.: 18/416,802

(22) Filed: Jan. 18, 2024

(30) Foreign Application Priority Data
Jul. 24, 2023 (KR) 10-2023-0096254

(51) Int. Cl. C23C 16/455; C23C 16/54

(52) U.S. Cl. CPC C23C 16/455; C23C 16/54

(57) ABSTRACT

Provided are a substrate processing apparatus and a substrate processing method, which are capable of independently performing processes on a plurality of substrates in a multi-station chamber. The substrate processing apparatus includes a multi-station chamber including a first process station, a second process station, a third process station, and a fourth process station, each of which independently performs processes, and configured to perform processes for a plurality of substrates, a gas supply unit configured to divide a plurality of gases to respectively supply the plurality of gases to the first process station, the second process station, the third process station, and the fourth process station, and a control unit configured to control the gas supply unit so that the plurality of gases are sequentially supplied to the first to fourth process stations by alternating the gases supplied between the first process station, the second process station, the third process station, and the fourth process station.

### CROSS-REFERENCE TO RELATED APPLICATION

This application claims priority to Korean Patent Application No. 10-2023-0096254 filed on Jul. 24, 2023 and all the benefits accruing therefrom under 35 U.S.C. § 119, the contents of which are incorporated by reference in their entirety.

### BACKGROUND

The present disclosure relates to a substrate processing apparatus and a substrate processing method, and more particularly, to a substrate processing apparatus and a substrate processing method, which are capable of independently performing processes on a plurality of substrates in a multi-station chamber.

A substrate processing apparatus may be an apparatus for depositing reaction particles contained in a process gas injected into a processing space by using a chemical vapor deposition (CVD) method or an atomic layer deposition (ALD) method after disposing a substrate to be processed in the processing space and may be classified into a single wafer-type substrate processing apparatus that is capable of performing a processing process on one substrate and a batch-type substrate processing apparatus that is capable of performing a processing process on a plurality of substrates at the same time.

In general, the batch-type substrate processing apparatus may perform the processing process by accommodating a plurality of substrates in multiple stages in a process tube having a vertical structure. In the batch-type substrate processing apparatus, a process gas may not be injected perpendicular to a deposition surface of the substrate, but may be injected laterally to cause a limitation in which a deposition rate varies depending on a distance from an injection nozzle.

In addition, the single wafer-type substrate processing apparatus has a disadvantage of low process yield as the substrate processing apparatus processes only one substrate in one chamber.

Thus, there is a need for a substrate processing apparatus that is capable of performing a process a plurality of substrates in one chamber while injecting a process gas perpendicular to a deposition surface of the substrates.

### SUMMARY

The present disclosure provides a substrate processing apparatus and a substrate processing method, which perform different processes at each process station by separately supplying a plurality of gases to the plurality of process stations.

In accordance with an exemplary embodiment, a substrate processing apparatus includes: a multi-station chamber including a first process station, a second process station, a third process station, and a fourth process station, each of which independently performs processes, and configured to perform processes for a plurality of substrates; a gas supply unit configured to divide a plurality of gases to respectively supply the plurality of gases to the first process station, the second process station, the third process station, and the fourth process station; and a control unit configured to control the gas supply unit so that the plurality of gases are sequentially supplied to the first to fourth process stations by alternating the gases supplied between the first process station, the second process station, the third process station, and the fourth process station.

The gas supply unit may include: a first gas supply part configured to supply a first process gas to the multi-station chamber; a second gas supply part configured to supply a second process gas different from the first process gas to the multi-station chamber; a first purge supply part configured to supply a first purge gas to the multi-station chamber; and a second purge supply part configured to supply a second purge gas to the multi-station chamber.

The control unit may control the first gas supply part, the second gas supply part, the first purge supply part, and the second purge supply part so that the first process gas, the second process gas, the first purge gas, and the second purge gas are divided to be respectively supplied to different process stations of the first process station, the second process station, the third process station, the third process station, and the fourth process station.

The second process station may be disposed in a first direction of the first process station, the fourth process station may be disposed in a second direction perpendicular to the first direction of the first process station, and the third process station may be disposed in a diagonal direction between the first direction and the second direction of the first process station.

The control unit may be configured to: control the first gas supply part so that the first process gas is supplied in order of the first process station, the second process station, the third process station, and the fourth process station; control the first purge supply part so that the first purge gas is supplied in order of the fourth process station, the first process station, the second process station, and the third process station; control the second gas supply part so that the second process gas is supplied in order of the third process station, the fourth process station, the first process station, and the second process station; and control the second purge supply part so that the second purge gas is supplied in order of the second process station, the third process station, the fourth process station, and the first process station.

The first gas supply part may include a first gas reservoir connected to each of the first process station, the second process station, the third process station, and the fourth process station and configured to store the first process gas so as to selectively supply the first process gas to the first process station, the second process station, the third process station, and the fourth process station, the second gas supply part may include a second gas reservoir connected to each of the first process station, the second process station, the third process station, and the fourth process station and configured to store the second process gas so as to selectively supply the second process gas to the first process station, the second process station, the third process station, and the fourth process station, the first purge supply part may include a first purge reservoir connected to each of the first process station, the second process station, the third process station, and the fourth process station and configured to store the first purge gas so as to selectively supply the first purge gas to the first process station, the second process station, the third process station, and the fourth process station, and the second purge supply part may include a second purge reservoir connected to each of the first process station, the second process station, the third process station, and the fourth process station and configured to store the second purge gas so as to selectively supply the second purge gas to the first process station, the second process station, the third process station, and the fourth process station.

Each of the first gas reservoir and the second gas reservoir may have a size different from that of each of the first purge reservoir and the second purge reservoir.

Each of the first purge reservoir and the second purge reservoir may have a size less than that of each of the first gas reservoir and the second gas reservoir.

The first purge reservoir and the second purge reservoir may have the same size.

The first gas supply part may further include a plurality of first gas valves provided between each of the first process station, the second process station, the third process station, and the fourth process station and the first gas reservoir, the second gas supply part may further include a plurality of second gas valves provided between each of the first process station, the second process station, the third process station, and the fourth process station and the second gas reservoir, the first purge supply part may further include a plurality of first purge valves provided between each of the first process station, the second process station, the third process station, and the fourth process station and the first purge reservoir, and the second purge supply part may further include a plurality of second purge valves provided between each of the first process station, the second process station, the third process station, and the fourth process station and the second purge reservoir.

The substrate processing apparatus may further include a plurality of valve blocks on which the first gas valve, the second gas valve, the first purge valve, and the second purge valve are supported, respectively, and which are provided on upper portions of the first process station, the second process station, the third process station, and the fourth process station, respectively.

In accordance with another exemplary embodiment, a substrate processing method using a multi-station chamber including a first process station, a second process station, a third process station, and a fourth process station, in which respective processes are independently performed, includes: a first process of dividing a plurality of gases to primarily supply gases to the first process station, the second process station, the third process station, and the fourth process station, respectively; a second process of dividing the plurality of gases to secondarily supply gases so that the gases different from the gases supplied in the first process are supplied to the first process station, the second process station, the third process station, and the fourth process station, respectively; a third process of dividing the plurality of gases to tertiarily supply gases so that the gases different from the gases supplied in the second process are supplied to the first process station, the second process station, the third process station, and the fourth process station, respectively, and a fourth process of dividing the plurality of gases to quaternarily supply gases so that the gases different from the gases supplied in the third process are supplied to the first process station, the second process station, the third process station, and the fourth process station, respectively.

The plurality of gases may include a first process gas, a second process gas different from the first process gas, a first purge gas, and a second purge gas, wherein the first process may include a process of supplying the first process gas, the second purge gas, the second process gas, and the first purge gas to the first process station, the second process station, the third process station, and the fourth process station, respectively; the second process may include a process of supplying the first purge gas, the first process gas, the second purge gas, and the second process gas to the first process station, the second process station, the third process station, and the fourth process station, respectively; the third process may include a process of supplying the second process gas, the first purge gas, the first process gas, and the second purge gas to the first process station, the second process station, the third process station, and the fourth process station, respectively; and the fourth process may include a process of supplying the second purge gas, the second process gas, the first purge gas, and the first process gas to the first process station, the second process station, the third process station, and the fourth process station, respectively.

The second process station may be disposed in a first direction of the first process station, the fourth process station may be disposed in a second direction perpendicular to the first direction of the first process station, and the third process station may be disposed in a diagonal direction between the first direction and the second direction of the first process station.

The first process gas and the second process gas may be different from the first purge gas and the second purge gas in at least one of an injection amount, an injection pressure, or an injection speed in the first process, the second process, the third process, and the fourth process.

In the first process, the second process, the third process, and the fourth process, at least one of the injection amount, the injection pressure, or the injection speed of the first purge gas and the second purge gas may be the same.

### BRIEF DESCRIPTION OF THE DRAWINGS

Exemplary embodiments can be understood in more detail from the following description taken in conjunction with the accompanying drawings, in which:

FIG. 1 is a schematic view of a substrate processing apparatus in accordance with an exemplary embodiment;

FIG. 2 is a schematic cross-sectional view of a multi-station chamber in accordance with an exemplary embodiment;

FIG. 3 is a conceptual view for explaining supply of a gas to each process station in accordance with an exemplary embodiment;

FIG. 4 is a flowchart illustrating a substrate processing method in accordance with another exemplary embodiment; and

FIG. 5 is a conceptual view for explaining supply of a gas to each process station by a time period in accordance with another exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

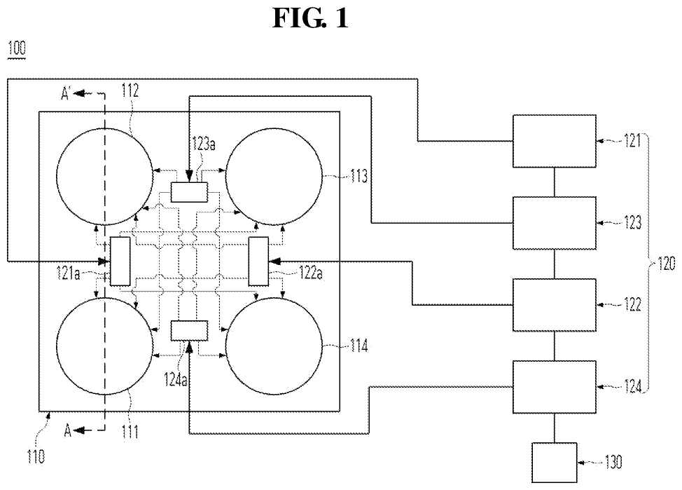

FIG. 1 is a schematic view of a substrate processing apparatus in accordance with an exemplary embodiment.

Referring to FIG. 1, a substrate processing apparatus 100 in accordance with an exemplary embodiment may include a multi-station chamber 110 including a first process station 111, a second process station 112, a third process station 113, and a fourth process station 114, each of which independently performs processes, and configured to perform processes for a plurality of substrates 10, a gas supply unit 120 that divides the plurality of gases to respectively supply the plurality of gases to the first process station 111, the second process station 112, the third process station 113, and the fourth process station 114, and a control unit 130 that controls the gas supply unit 120 so that the plurality of gases are sequentially supplied to the first to fourth process stations 111, 112, 113, and 114 by alternating the gases supplied between the first process station 111, the second process station 112, the third process station 113, and the fourth process station 114.

The multi-station chamber 110 may include a first process station 111, a second process station 112, a third process station 113, and a fourth process state 114, which perform processes on the plurality of substrates 10, and each of which independently performs the processes. Here, the first process station 111, the second process station 112, the third process station 113, and the fourth process station 114 may be regionally divided within one multi-station chamber 110 and may communicate with each other so as not spatially separated (or isolated) by partition walls, like the plurality of chambers.

Here, the first process station 111, the second process station 112, the third process station 113, and the fourth process station 114 may independently perform the processes, respectively, and also, each of the process stations may include the same configurations such as a shower head and a substrate support, and numbers of the process stations may be only differentiated by their positions (or areas).

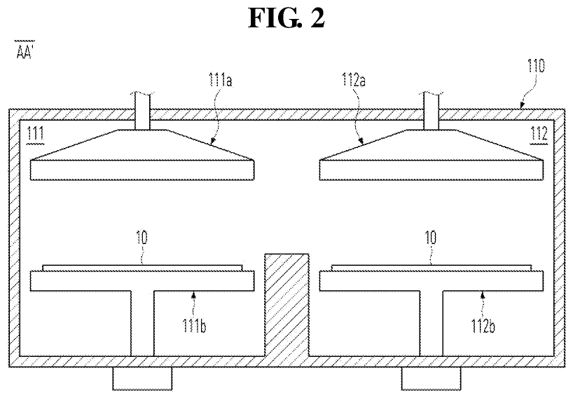

FIG. 2 is a schematic cross-sectional view of the multi-station chamber in accordance with an exemplary embodiment, i.e., a cross-sectional view of the multi-station chamber, taken along line A-A′ of FIG. 1.

Referring to FIG. 2, each of the first process station 111, the second process station 112, the third process station 113, and the fourth process station 114 may include a shower head through which a gas is injected and a substrate support on which (one) substrate 10 is supported. The shower head may inject a gas for processing the substrate on the substrate 10, and the substrate support may support the substrate 10 to be processed. The gas may be injected onto the substrate 10 supported on the substrate support to perform substrate processing such as deposition.

For example, the first process station 111 may include a first substrate support 111b on which a first substrate 10 is supported, and a first shower head 111a provided on the first substrate support 111b to inject a gas for substrate processing onto the first substrate 10 supported on the first substrate support 111b, and the second process station 112 may include a second substrate support 112b on which a second substrate 10 is supported, and a second shower head 112a provided on the second substrate support 112b to inject a gas for substrate processing onto the second substrate 10 supported on the second substrate supporter 112b.

Each of the first shower head 111a and the second shower head 112a may be connected to the gas supply unit 120, and the first shower head 111a and the second shower head 112a may be provided to the first process station 111 and the second process station 112, respectively, and thus, one of the plurality of gases may be selectively supplied, and the supplied gas may be injected. Here, the same gas or different gases may be supplied to the first shower head 111a and the second shower head 112a.

In addition, the first substrate support 111b and the second substrate support 112b may be provided in the first process station 111 and the second process station 112 to support the first substrate 10 and the second substrate 10, respectively. As a result, the processing of the plurality of substrates 10 may be performed at the same time in one multi-station chamber 110, and thus, process yield may be improved.

The gas supply unit 120 may selectively supply the plurality of gases to the first process station 111, the second process station 112, the third process station 113, and the fourth process station 114. The plurality of gases may be divided to be respectively supplied to the first process station 111, the second process station 112, the third process station 113, and the fourth process station 114, respectively. The gas supply unit 120 may supply the same gas to all the first process station 111, the second process station 112, the third process station 113, and the fourth process station 114. Alternatively, different gases may be supplied to the first process station 111, the second process station 112, the third process station 113, and the fourth process station 114, or a different gas from the other process station(s) may be supplied to at least one process station of the first process station 111, the second process station 112, third process station 113, and fourth process station 114. Here, the number of gas supply sources of the gas supply unit 120 may be the same as the number of the plurality of gases or the number of process stations, and also, the number of the process stations and the number of the plurality of gases may be the same.

Here, the gas supply unit 120 may include the gas supply source, and a gas supply line for supplying gases from the gas supply source to the first process station 111, the second process station 112, the third process station 113, and the fourth process station 114 of the multi-station chamber 110.

The control unit 130 may alternate the gas supplied between the first process station 111, the second process station 112, the third process station 113, and the fourth process station 114 to control the gas supply unit 120 so that the plurality of gases are sequentially (successively) supplied to the first to fourth process stations 111, 112, 113, and 114, and the supplied gases may be alternately supplied to the first process station 111, the second process station 112, the third process station 113, and the fourth process station 114 or may be supplied sequentially differently from the gas that is supplied immediately (or previously).

For example, the plurality of gases may be supplied to the first process station 111, the second process station 112, the third process station 113, and the fourth process station 114 in a predetermined order. Here, a gas to be supplied (next or later) may be determined depending on the gas supplied immediately before, and the gas may be supplied without overlapping (or duplicated) with the gas supplied immediately before.

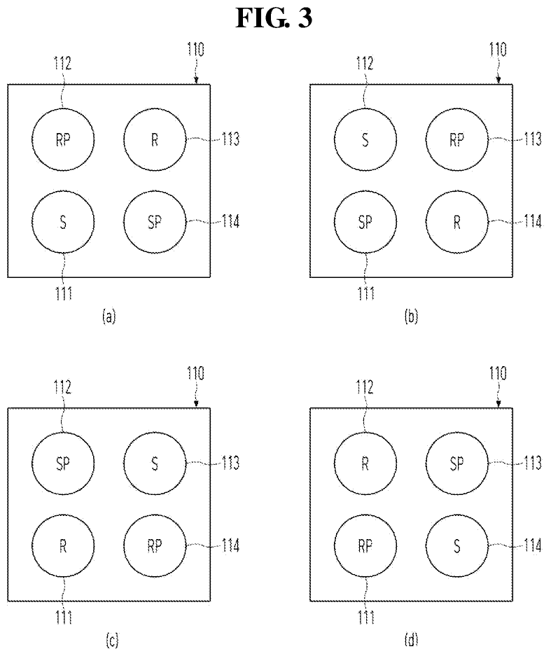

FIG. 3 is a conceptual view for explaining supply of a gas to each process station in accordance with an exemplary embodiment. (a) of FIG. 3 illustrates a first process of supplying a first process gas to the first process station, (b) of FIG. 3 illustrates a second process of supplying the first process gas to the second process station, (c) of FIG. 3 illustrates a third process of supplying the first process gas to the third process station, and (d) of FIG. 3 illustrates a fourth process of supplying the first process gas to the fourth process station. Here, the plurality of gases may be circulated in the following order: a first process gas→a first purge gas→a second process gas→a second purge gas, and the first process gas may be supplied after the second purge gas. Since the (supply) start gas is different at each process station, different gases may be supplied at the same time.

Referring to FIGS. 1 and 3, the gas supply unit 120 may include a first gas supply part 121 that supplies the first process gas to the multi-station chamber 110, a second gas supply part 122 that supplies the second process gas different from the first process gas to the multi-station chamber 110, a first purge supply part 123 that supplies the first purge gas to the multi-station chamber 110, and a second purge supply part 124 that supplies the second purge gas to the multi-station chamber 110. The first gas supply part 121 may supply the first process gas to the multi-station chamber 110 and may be connected to each of the first process station 111, the second process station 112, the third process station 113, and the fourth process station 114 to supply the first process gas. For example, the first gas supply part 121 may include a first process gas supply source connected to the shower head of each of the first process station 111, the second process station 112, the third process station 113, and the fourth process station 114 and a first process gas supply line that supplies the first process gas to the shower head of each of the first process station 111, the second process station 112, the third process station 113, and the fourth process station 114 from the first process gas supply source. Here, the first process gas may be a source gas S and may include titanium tetrachloride (TiCl₄), dichlorosilane DCS (SiH₂Cl₂), etc.

The second gas supply part 122 may supply the second process gas, which is different from the first process gas, to the multi-station chamber 110 and may be connected to each of the first process station 111, the second process station 112, the third process station 113, and the fourth process station 114 to supply the second process gas. For example, the second gas supply part 122 may include a second process gas supply source connected to the shower head of each of the first process station 111, the second process station 112, the third process station 113, and the fourth process station 114 and a second process gas supply line that supplies the second process gas to the shower head of each of the first process station 111, the second process station 112, the third process station 113, and the fourth process station 114 from the second process gas supply source. Here, the second process gas may be a reactant gas R that reacts with the source gas and may include ammonia (NH₃), hydrogen (H₂), etc.

The first purge supply part 123 may supply the first purge gas to the multi-station chamber 110 and may be connected to each of the first process station 111, the second process station 112, the third process station 113, and the fourth process station 114 to supply the first purge gas. For example, the first purge supply part 123 may include a first purge gas supply source connected to the shower head of each of the first process station 111, the second process station 112, the third process station 113, and the fourth process station 114 and a first purge gas supply line that supplies the first purge gas to the shower head of each of the first process station 111, the second process station 112, the third process station 113, and the fourth process station 114 from the first purge gas supply source. Here, the first purge gas may be a source purge gas SP that purges the source gas (or the first process gas) or may be an inert gas. The first purge gas may include nitrogen (N₂), hydrogen (H₂), and argon (Ar), but is not particularly limited thereto.

The second purge supply part 124 may supply the second purge gas to the multi-station chamber 110 and may be connected to each of the first process station 111, the second process station 112, the third process station 113, and the fourth process station 114 to supply the second purge gas. For example, the second purge supply part 124 may include a second purge gas supply source connected to the shower head of each of the first process station 111, the second process station 112, the third process station 113, and the fourth process station 114 and a second purge gas supply line that supplies the second purge gas to the shower head of each of the first process station 111, the second process station 112, the third process station 113, and the fourth process station 114 from the second purge gas supply source. Here, the second purge gas may be a reactant purge gas RP that purges the reactant gas (or the second process gas) or may be an inert gas. The second purge gas may include nitrogen (N₂), hydrogen (H₂), and argon (Ar), but is not particularly limited thereto. Here, the first purge gas and the second purge gas may be the same or different types of gas, and at least their functions and supply (or injection) order depending on the functions may be different. The first purge gas and the second purge gas may be different in at least one of an injection amount, an injection pressure, or an injection speed depending on their functions, but all the injection amount, the injection pressure, and the injection speed may be the same.

The control unit 130 may control the first gas supply part 121, the second gas supply part 122, the first purge supply part 123, and the second purge supply part 124 so that the first process gas, the second process gas, the first purge gas, and the second purge gas are divided to be respectively supplied to different process stations of the first process station 111, the second process station 112, the third process station 113, the third process station 113, and the fourth process station 114. The control unit 130 may control the first gas supply part 121, the second gas supply part 122, the first purge supply part 123, and the second purge supply part 124 so that the first process gas, the second process gas, the first purge gas, and the second purge gas are divided to be respectively supplied to different process stations of the first process station 111, the second process station 112, the third process station 113, and the fourth process station 114 and to respectively supply the first process gas, the second process gas, the first purge gas, and the second purge gas to the first process station 111, the second process station 112, the third process station 113, and the fourth process station 114.

That is, as will be described in detail later in the substrate processing method in accordance with another exemplary embodiment, different gases may be supplied to the first process station 111, the second process station 112, the third process station 113, and the fourth process station 114 at the same time period (or time) to perform different processes. Here, the different gases may have the same type, but may include that (or case in which) the gases are different in only their functions.

For example, the first process gas may be supplied (first) to the first process station 111 to perform a process of depositing a first layer (e.g., source material layer) or first atomic layer, the second purge gas may be supplied (first) to the second process station 112 to perform a process of purging (the second process gas), the second process gas may be supplied (first) to the third process station 113 to perform a process of depositing a second layer (e.g., reactive material layer) or second atomic layer, and the first purge gas may be supplied (first) to the fourth process station 114 to perform a process of purging (the first process gas). The substrate processing apparatus 100 of the present disclosure may perform not only chemical vapor deposition (CVD) but also atomic layer deposition (ALD), and the first process gas and the second process gas may be deposited into units of an atomic layer.

Thus, in the substrate processing apparatus 100 in accordance with an exemplary embodiment, the plurality of gases (i.e., the first process station 111, the second process station 112, the third process station 113, and the fourth process station 114 of the multi-station chamber 110) may be divided to be supplied to the first process station 111, the second process station 112, the third process station 113, and the fourth process station 114 of the multi-station chamber 110, respectively, so that a certain amount of gas(es) is always supplied into the multi-station chamber 110, and thus, a pressure within the multi-station chamber 110 may be controlled to a stable process pressure, and the process pressure within the multi-station chamber 110 may be maintained constantly (or equally). As a result, contamination of the multi-station chamber 110 due to a rapid change in process pressure within the multi-station chamber 110 due to a change in gas may be improved.

In the related art, since the same gas is supplied at the same time to the plurality of process stations in the multi-station chamber 110, and the overall gas (or the gas supplied to the plurality of process stations at the same time) is changed in accordance with the order (or time), the process pressure in the multi-station chamber 110 changed rapidly in accordance with the (overall) change in gas, and as a result, there is a limitation in that the multi-station chamber 110 is easily contaminated due to process residues, particles, etc. sticking to an inner wall of the multi-station chamber 110.

However, in the present disclosure, since only the process station to which each gas is supplied is different, but the first process gas, the second process gas, the first purge gas, and the second purge gas are always maintained in the multi-station chamber 110 under the same injection conditions (e.g., the injection amount, the injection pressure, and the injection speed, etc.), the process pressure within the multi-station chamber 110 may be maintained constantly without the sudden change in the process pressure within the multi-station chamber 110, and the pressure within the multi-station chamber 110 may be controlled to a stable process pressure. Thus, the limitation in which the multi-station chamber 110 in accordance with the related art is easily contaminated due to the rapid changes in process pressure may be improved.

Here, the second process station 112 may be disposed in a first direction of the first process station 111, the fourth process station 114 may be disposed in a second direction perpendicular to the first direction of the first process station 111, and the third process station 113 may be disposed in a diagonal direction between the first direction and the second direction of the first process station 111. That is, the first process station 111 and the third process station 113 may be disposed in the diagonal direction with respect to each other, the second process station 112 and the fourth process station 114 may be disposed in the diagonal direction with respect to each other, and the first process station 111, the second process station 112, the third process station 113, and the fourth process station 114 may be disposed in a clockwise or counterclockwise direction. Here, when the first process gas and the second process gas are supplied to the first process station 111 and the third process station 113, respectively, the first purge gas and the second purge gas may be supplied to the second process station 112 and the fourth process station 114, respectively, and when the first process gas and the second process gas are supplied to the second process station 112 and the fourth process station 114, respectively, the first purge gas and the second purge gas may be supplied to the first process station 111 and the third process station 113, respectively.

In this case, each of the first purge gas and the second purge gas may function as an air curtain in the diagonal direction, even without the configuration of the additional (separate) air curtain, (a space of) the process station to which the first process gas is supplied and (a space of) the process station to which the second process gas is supplied may be separated (or divided), and deposition may be performed independently of the process station, into which the first process gas is supplied, and the process station, into which the second process gas is supplied, without a mutual influence.

If the process station, to which the first process gas is supplied, and the process station, to which the second process gas is supplied (for example, the first process station and the third process station or the second process station and the fourth process station) are disposed (to be in contact with each other) in the first direction or the second direction, the process station, to which the first process gas is supplied, and the process station, to which the second process gas is supplied, may communicate with each other, and thus, the second process gas may affect the process station, to which the first process gas is supplied, and the first process gas may affect the process station, to which the second process gas is supplied.

However, as in the present disclosure, when the process station, to which the first process gas is supplied, and the process station, to which the second process gas is supplied, are disposed in the diagonal direction, the communication therebetween may be blocked by the first purge gas and the second purge gas of the process station, to which the first purge gas is supplied, and the process station, to which the second purge gas is supplied, to isolate (separate) the process station, to which the first process gas is supplied, from the process state, to which the second process gas is supplied.

In addition, the control unit 130 may control the first gas supply part 11 so that the first process gas is supplied in order of the first process station 111, the second process station 112, the third process station 113, and the fourth process station 114, control the first purge supply part 123 so that the first purge gas is supplied in order of the fourth process station 114, the first process station 111, the second process station 112, and the third process station 113, control the second gas supply part 133 so that the second process gas is supplied in order of the third process station 113, the fourth process station 114, the first process station 111, and the second process station 112, and control the second purge supply part 124 so that the second purge gas is supplied in order of the second process station 112, the third process station 113, the fourth process station 114, and the first process station 111.

That is, the gases may be supplied to the first process station 111 in order of: the first process gas S→the first purge gas SP→the second process gas R→the second purge gas RP, may be supplied to the second process station 112 in order of: the second purge gas RP→the first process gas S→the first purge gas SP→the second process gas R, may be supplied to the third process station 113 in order of: the second process gas R→the second purge gas RP→the first process gas S→the first purge gas SP, and may be supplied to the fourth process station 114 in order of: the first purge gas SP→the second process gas R→the second purge gas RP→the first process.

Thus, since different gases are supplied to respective process stations at the same time, the amount and/or pressure of gas supplied between the first process station 111, the second process station 112, the third process station 113, and the fourth process station 114 may be controlled constantly to improve the thickness uniformity of the thin film deposited in each process station may be controlled to be constant, and thus, the thickness uniformity of the thin film deposited at each process station may be improved. That is, since each of the first process gas, the second process gas, the first purge gas, and the second purge gas are supplied (sequentially) to the process stations, the amount and pressure of each gas may be adjusted and reflected immediately. When the same gas is supplied at the same time to two or more process stations, the amount and/or pressure of the gas may be different between the two or more process stations, and even if the amount and pressure of the gas are adjusted, a reflection rate may vary for each process station, and also, the amount and pressure of the gas may not be adjusted well.

That is, in the substrate processing apparatus 100 in accordance with an exemplary embodiment, the different processes may be respectively performed in the process stations through the substrate processing method in accordance with an exemplary embodiment, in which the first process gas, the second process gas, the first purge gas, and the second purge gas are divided to be respectively supplied to the first process station 111, the second process station 112, the third process station 113, and the fourth process station 114 to sequentially supply the first process gas, the first purge gas, the second process gas, and the second purge gas into the respective process stations, and thus, the thin film having the uniform thickness may be deposited in each process station, and the gas supply efficiency may be improved.

The first gas supply part 121 may include a first gas reservoir 121a connected to each of the first process station 111, the second process station 112, the third process station 113, and the fourth process station 114 and storing the first process gas to selectively supply the first process gas to the first process station 111, the second process station 112, the third process station 113, and the fourth process station 114, the second gas supply part 122 may include a second gas reservoir 122a connected to each of the first process station 111, the second process station 112, the third process station 113, and the fourth process station 114 and storing the second process gas to selectively supply the second process gas to the first process station 111, the second process station 112, the third process station 113, and the fourth process station 114, the first purge supply part 123 may include a first purge reservoir 123a connected to each of the first process station 111, the second process station 112, the third process station 113, and the fourth process station 114 and storing the first purge gas to selectively supply the first purge gas to the first process station 111, the second process station 112, the third process station 113, and the fourth process station 114, and the second purge supply part 124 may include a second purge reservoir 124a connected to each of the first process station 111, the second process station 112, the third process station 113, and the fourth process station 114 and storing the second purge gas to selectively supply the second purge gas to the first process station 111, the second process station 112, the third process station 113, and the fourth process station 114. The first gas reservoir 121a may be provided between (or in the middle of) the first process gas supply source and the multi-station chamber 110 to store the first process gas and may be connected to each of the first process station 111, the second process station 112, the third process station 113, and the fourth process station 114 to supply the first process gas to the first process station 111, the second process station 112, the third process station 113, and the fourth process station 114. Even if the instantaneous supply or blocking (or opening/closing) of the first process gas is repeated between the first process station 111, the second process station 112, the third process station 113, and the fourth process station 114 through the first gas reservoir 121a, the injection amount, the injection pressure, and the injection speed may be maintained stably, and the injection amount, the injection pressure, and the injection speed of the first process gas in each of the first process station 111, the second process station 112, the third process station 113, and the fourth process station 114 may be efficiently controlled.

For example, the supply and blocking of the first process gas may be achieved by opening and closing a valve, and the supply and blocking of the first process gas and the injection amount, the injection pressure, and the injection speed of the first process gas may be immediately adjusted in accordance with the opening and closing of the valve.

The second gas reservoir 122a may be provided between the second process gas supply source and the multi-station chamber 110 to store the second process gas and may be connected to each of the first process station 111, the second process station 112, the third process station 113, and the fourth process station 114 to supply the second process gas to the first process station 111, the second process station 112, the third process station 113, and the fourth process station 114. Even if the instantaneous supply or blocking of the second process gas is repeated between the first process station 111, the second process station 112, the third process station 113, and the fourth process station 114 through the second gas reservoir 122a, the injection amount, the injection pressure, and the injection speed may be maintained stably, and the injection amount, the injection pressure, and the injection speed of the second process gas in each of the first process station 111, the second process station 112, the third process station 113, and the fourth process station 114 may be efficiently controlled.

For example, the supply and blocking of the second process gas may be achieved by opening and closing a valve, and the supply and blocking of the second process gas and the injection amount, the injection pressure, and the injection speed of the second process gas may be immediately adjusted in accordance with the opening and closing of the valve.

The first purge reservoir 123a may be provided between the first purge gas supply source and the multi-station chamber 110 to store the first purge gas and may be connected to each of the first process station 111, the second process station 112, the third process station 113, and the fourth process station 114 to supply the first purge gas to the first process station 111, the second process station 112, the third process station 113, and the fourth process station 114. Even if the instantaneous supply or blocking of the first purge gas is repeated between the first process station 111, the second process station 112, the third process station 113, and the fourth process station 114 through the first purge reservoir 123a, the injection amount, the injection pressure, and the injection speed may be maintained stably, and the injection amount, the injection pressure, and the injection speed of the first purge gas in each of the first process station 111, the second process station 112, the third process station 113, and the fourth process station 114 may be efficiently controlled.

For example, the supply and blocking of the first purge gas may be achieved by opening and closing a valve, and the supply and blocking of the first purge gas and the injection amount, the injection pressure, and the injection speed of the first purge gas may be immediately adjusted in accordance with the opening and closing of the valve.

The second purge reservoir 124a may be provided between the second purge gas supply source and the multi-station chamber 110 to store the second purge gas and may be connected to each of the first process station 111, the second process station 112, the third process station 113, and the fourth process station 114 to supply the second purge gas to the first process station 111, the second process station 112, the third process station 113, and the fourth process station 114. Even if the instantaneous supply or blocking of the second purge gas is repeated between the first process station 111, the second process station 112, the third process station 113, and the fourth process station 114 through the second purge reservoir 124a, the injection amount, the injection pressure, and the injection speed may be maintained stably, and the injection amount, the injection pressure, and the injection speed of the second purge gas in each of the first process station 111, the second process station 112, the third process station 113, and the fourth process station 114 may be efficiently controlled.

For example, the supply and blocking of the second purge gas may be achieved by opening and closing a valve, and the supply and blocking of the second purge gas and the injection amount, the injection pressure, and the injection speed of the second purge gas may be immediately adjusted in accordance with the opening and closing of the valve.

Here, each of the first gas reservoir 121a and the second gas reservoir 122a may have a different size from that of each of the first purge reservoir 123a and the second purge reservoir 124a. Since the first gas reservoir 121a and the second gas reservoir 122a store the process gases of the first process gas and the second process gas, and the first purge reservoir 123a and the second purge reservoir 124a store the purge gases of the first purge gas and the second purge gas, their sizes may be different from each other. As a result, the first purge gas and the second purge gas may effectively perform the role of the air curtain while performing the role of the purge, and the first process gas and the second process gas may be effectively deposited on the substrate 10 without an influence of the first purge gas and the second purge gas.

Here, each of the first purge reservoir 121a and the second purge reservoir 122a may be (relatively) smaller than each of the first gas reservoir 123a and the second gas reservoir 124a. Since each of the first purge reservoir 121a and the second purge reservoir 122a is smaller than that of the first gas reservoir 123a and the second gas reservoir 124a, the injection pressure and injection speed (or gas movement speed) of the first purge gas and the second purge gas may increase while the injection amount (per unit time) of each of the first purge gas and the second purge gas decreases. Thus, the role of the air curtain may be effectively performed through the high (or large) injection pressure and fast injection speed of each of the first purge gas and the second purge gas, and the process station to which the first process gas is supplied and the process station to which the second process gas is supplied may be effectively separated (or isolated) from each other. In addition, due to the high injection pressure and the fast injection speed of each of the first purge gas and the second purge gas, the first purge gas and the second purge gas may be quickly exhausted directly without affecting the process station to which the first process gas is supplied and the process station to which the second process gas is supplied.

Since each of the first gas reservoir 123a and the second gas reservoir 124a is (relatively) larger than each of the first purge reservoir 121a and the second purge reservoir 122a, the injection amount (per unit time) of each of the first process gas and the second process gas may (relatively) increase to prevent the first purge gas and/or the second purge gas from being invaded int areas (or spaces) of the process station to which the first process gas is supplied and the process station to which the second process gas is supplied, thereby securing a deposition space of the first process gas or the second process gas. As a result, the first process gas and the second process gas may be effectively and uniformly deposited on the substrate 10 without the influence of the first purge gas and the second purge gas. In addition, a phenomenon in which the injection pressure and injection speed of each of the first process gas and the second process gas decreases, and thus, the first process gas and the second process gas are directly exhausted without reacting (deposited) on a surface of the substrate 10 may be prevented from occurring.

In addition, the first purge reservoir 121a and the second purge reservoir 122a may have the same size. The first purge reservoir 121a and the second purge reservoir 122a may have the same size to generate the air curtain through the first purge gas and the second purge gas in the diagonal direction. Thus, the (process) pressure within each of the process station to which the first process gas is supplied and the process station to which the second process gas is supplied may be uniform overall, and the first process gas and the second process gas may be uniformly deposited on the entire surface of the substrate 10. Here, the first purge gas and the second purge gas may be the same type of gas, and the injection amount, the injection pressure, and the injection speed may be the same.

The first gas reservoir 123a and the second gas reservoir 124a may have the same or different sizes depending on the first process gas and the second process gas.

The first gas supply part 121 may further include a plurality of first gas valves (not shown) provided between each of the first process station 111, the second process station 112, the third process station 113, and the fourth process station 114 and the first gas reservoir 121a, the second gas supply part 122 may further include a plurality of second gas valves (not shown) provided between each of the first process station 111, the second process station 112, the third process station 113, and the fourth process station 114 and the second gas reservoir 122a, the first purge supply part 123 may further include a plurality of first purge valves (not shown) provided between each of the first process station 111, the second process station 112, the third process station 113, and the fourth process station 114 and the first purge reservoir 123a, and the second purge supply part 124 may further include a plurality of second purge valves (not shown) provided between each of the first process station 111, the second process station 112, the third process station 113, and the fourth process station 114 and the second purge reservoir 124a. The plurality of first gas valves (not shown) may be provided between each of the first process station 111, the second process station 112, the third process station 113, and the fourth process station 114 and the first gas reservoir 121a, and the control unit 130 may control the first gas supply part 121 so that the first process gas is supplied in order of the first process station 111, the second process station 112, the third process station 113, and the fourth process station 114 through the plurality of first gas valves (not shown).

The plurality of second gas valves (not shown) may be provided between each of the first process station 111, the second process station 112, the third process station 113, and the fourth process station 114 and the second gas reservoir 122a, and the control unit 130 may control the second gas supply part 122 so that the second process gas is supplied in order of the third process station 113, the fourth process station 114, the first process station 111, and the second process station 112 through the plurality of second gas valves (not shown).

The plurality of first purge valves (not shown) may be provided between each of the first process station 111, the second process station 112, the third process station 113, and the fourth process station 114 and the first purge reservoir 123a, and the control unit 130 may control the first purge supply part 123 so that the first purge gas is supplied in order of the fourth process station 114, the first process station 111, the second process station 112, and the third process station 113 through the plurality of first purge valves (not shown).

The plurality of second purge valves (not shown) may be provided between each of the first process station 111, the second process station 112, the third process station 113, and the fourth process station 114 and the second purge reservoir 124a, and the control unit 130 may control the second purge supply part 124 so that the second purge gas is supplied in order of the second process station 112, the third process station 113, the fourth process station 114, and the first process station 111 through the plurality of second purge valves (not shown).

Here, the substrate processing apparatus 100 in accordance with an exemplary embodiment may further include a plurality of valve blocks (not shown) on which each of a first gas valve (not shown), a second gas valve (not shown), a first purge valve (not shown), and a second purge valve (not shown) is supported, and which is provided on each of upper portions of the first process station 111, the second process station 112, the third process station 113, and the fourth process station 114.

The plurality of valve blocks (not shown) may be provided on each of the upper portions of the first process station 111, the second process station 112, the third process station 113, and the fourth process station 114 to support the first gas valve (not shown), the second gas valve (not shown), the second gas valve (not shown), the first purge valve (not shown), and the second purge valve (not shown) that are provided respectively on the first process station 111, the second process station 112, the third process station 113, and the fourth process station 114.

For example, the plurality of valve blocks (not shown) may be installed to close (or adjacent) to each of shower heads of the first process station 111, the second process station 112, the third process station 113, and the fourth process station 114 so that the first gas valve (not shown), the second gas valve (not shown), the first purge valve (not shown), and the second purge valve (not shown) are (directly) connected to (or communicate with) (each) of the shower heads. Thus, the plurality of first gas valves (not shown), the plurality of second gas valves (not shown), the plurality of first purge valves (not shown), and the plurality of second purge valves (not shown) may be controlled through the control unit 130 so that each gas is injected (or supplied) or stopped (or blocked) instantly (or immediately). That is, the first process gas may be immediately injected through (each of) the shower heads, or the injection of the first process gas may be stopped in accordance with opening and closing of the plurality of first gas valves (not shown), the second process gas may be immediately injected through (each of) the shower heads, or the injection of the second process gas may be stopped in accordance with opening and closing of the plurality of second gas valves (not shown), the first purge gas may be immediately injected through (each of) the shower heads, or the injection of the first purge gas may be stopped in accordance with opening and closing of the plurality of first purge valves (not shown), and the second purge gas may be immediately injected through (each of) the shower heads, or the injection of the second purge gas may be stopped in accordance with opening and closing of the plurality of second purge valves (not shown).

As a result, (briefly) cut off (or delay) of the gas supply due to the opening/closing of the plurality of first gas valves (not shown), the plurality of second gas valves (not shown), the plurality of first purge valves (not shown), and the plurality of second purge valves in accordance with the change of gas may be suppressed or prevented. In accordance with the related art, since a distance between (each of) the shower heads and each valve is large, even if the valve is opened, it may take a time for the gas to be supplied (or moved) from the valve to (each of) the shower heads, and thus, the gas may not directly injected from (each of) of the shower heads. In addition, even if the valve is closed, the gas may still remain between the valve and (each of) the shower heads, and thus, the gas may not be blocked immediately until all of the remaining gases are injected, and the gas may be continuously injected. However, in the present disclosure, the plurality of first gas valves (not shown), the plurality of second gas valves (not shown), the plurality of first purge valves (not shown), and the plurality of second purge valve (not shown) may be installed to be close (as possible) to (each of) the shower heads through the plurality of valve blocks (not shown), and thus, the first process gas, the second process gas, the first purge gas, and the second purge gas may be injected through (each of) the shower heads, or the injection may be stopped immediately in accordance with the opening and closing of the plurality of first gas valves (not shown), the plurality of second gas valves (not shown), the plurality of first purge valves (not shown), and the plurality of second purge valves (not shown).

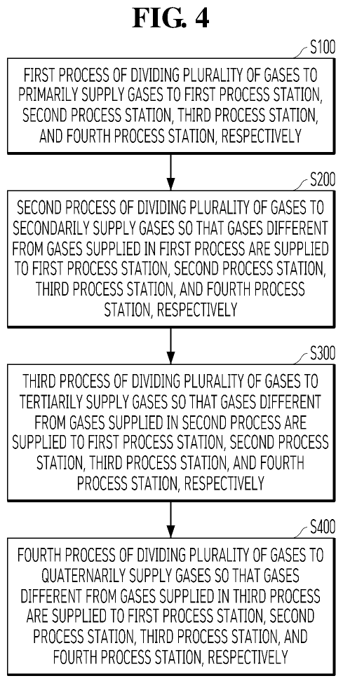

FIG. 4 is a flowchart illustrating a substrate processing method in accordance with another exemplary embodiment.

A method for processing a substrate processing method in accordance with another exemplary embodiment will be described with reference to FIG. 4. In the description of the substrate processing method in accordance with another exemplary embodiment, duplicated descriptions with respect to the substrate processing apparatus in accordance with an exemplary embodiment will be omitted.

A substrate processing method using a multi-station chamber 110 including a first process station 111, a second process station 112, a third process station 113, and a fourth process station 114, in which respective processes are independently performed, according to another exemplary embodiment may include a first process (S100) of dividing a plurality of gases to primarily supply gases to the first process station 111, the second process station 112, the third process station 113, and the fourth process station 114, respectively, a second process (S200) of dividing the plurality of gases to secondarily supply gases so that the gases different from the gases supplied in the first process (S100) are supplied to the first process station 111, the second process station 112, the third process station 113, and the fourth process station 114, respectively, a third process (S300) of dividing the plurality of gases to tertiarily supply gases so that the gases different from the gases supplied in the second process (S100) are supplied to the first process station 111, the second process station 112, the third process station 113, and the fourth process station 114, respectively, and a fourth process (S400) of dividing the plurality of gases to quaternarily supply gases so that the gases different from the gases supplied in the third process (S300) are supplied to the first process station 111, the second process station 112, the third process station 113, and the fourth process station 114, respectively.

First, in the first process (S100), the plurality of gases may be divided to be primarily supplied to the first process station 111, the second process station 112, the third process station 113, and the fourth process station 114. The plurality of gases may be divided to be primarily supplied to the first process station 111, the second process station 112, the third process station 113, and the fourth process station 114, and the first process station 111. Here, a gas different from the gas supplied to the other process station(s) may be supplied to at least one process station of the first process station 111, the second process station 112, the third process station 113, or the fourth process station 114.

Next, in the second process (S200), the plurality of gases may be divided to be secondarily supplied so that a gas different from the gas supplied in the first process (S100) is supplied to the first process station 111, the second process station 112, the third process station 113, and the fourth process station 114. The plurality of gases may be divided to be secondarily supplied so that a gas different from the gas supplied in the first process (S100) is supplied to the first process station 111, the second process station 112, the third process station 113, and the fourth process station 114, a gas different from the gas(es) supplied in the other process station(s) may be supplied to at least one of the first process station 111, the second process station 112, the third process station 113, or the fourth process station 114, and a gas different from the gas supplied in the first process (S100) may be supplied to each of the first process station 111, the second process station 112, the third process station 113, and the fourth process station 114.

Then, in the third process (S300), the plurality of gases may be divided to be tertiarily supplied so that a gas different from the gas supplied in the second process (S200) is supplied to the first process station 111, the second process station 112, the third process station 113, and the fourth process station 114. The plurality of gases may be divided to be tertiarily supplied so that a gas different from the gas supplied in the second process (S200) is supplied to the first process station 111, the second process station 112, the third process station 113, and the fourth process station 114. Here, a gas different from the gas(es) supplied in the other process station(s) may be supplied to at least one of the first process station 111, the second process station 112, the third process station 113, or the fourth process station 114, and a gas different from the gas supplied in the second process (S200) may be supplied to each of the first process station 111, the second process station 112, the third process station 113, and the fourth process station 114. Here, in the third process (S300), the gas supplied to each of the first process station 111, the second process station 112, the third process station 113, and the fourth process station 114 may be different from or the same as that supplied in the first process (S100), and it is sufficient that the gas is only different from that supplied in the second process (S200).

In addition, in the fourth process (S400), the plurality of gases may be divided to be quaternarily supplied so that a gas different from the gas supplied in the third process (S300) is supplied to the first process station 111, the second process station 112, the third process station 113, and the fourth process station 114. The plurality of gases may be divided to be quarternarily supplied so that a gas different from the gas supplied in the third process (S300) is supplied to the first process station 111, the second process station 112, the third process station 113, and the fourth process station 114, a gas different from the gas(es) supplied in the other process station(s) may be supplied to at least one of the first process station 111, the second process station 112, the third process station 113, or the fourth process station 114, and a gas different from the gas supplied in the third process (S300) may be supplied to each of the first process station 111, the second process station 112, the third process station 113, and the fourth process station 114. Here, in the fourth process (S400), the gas supplied to each of the first process station 111, the second process station 112, the third process station 113, and the fourth process station 114 may be different from or the same as that supplied in the first process (S100) and/or the second process (S200), and it is sufficient that the gas is only different from that supplied in the third process (S300).

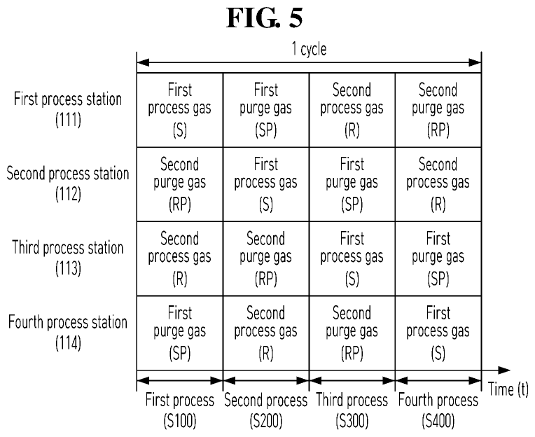

FIG. 5 is a conceptual view for explaining supply of a gas to each process station by a time period in accordance with another exemplary embodiment.

Referring to FIG. 5, the plurality of gases may include a first process gas, a second process gas different from the first process gas, a first purge gas, and a second purge gas. The first process gas may be a source gas S and may include titanium tetrachloride (TiCl₄), dichlorosilane DCS (SiH₂Cl₂), etc.

The second process gas may be different from the first process gas and may be a reactant gas R that reacts with the source gas and may include ammonia (NH₃), hydrogen (H₂), etc.

The first purge gas may purge the first process gas, may be a source purge gas SP that purges the source gas, may be an inert gas, and may be an inert gas. The first purge gas may be an inert gas and may include nitrogen (N₂), hydrogen (H₂), and argon (Ar), but is not particularly limited thereto.

The second purge gas may purge the second process gas, may be a reactive purge gas RP that purges the reactant gas, may be the inert gas. The second purge gas my include nitrogen (N₂), hydrogen (H₂), and argon (Ar), but is not particularly limited thereto. Here, the first purge gas and the second purge gas may be the same or different types of gas, and at least their functions and supply (or injection) order depending on the functions may be different. The first purge gas and the second purge gas may be different in at least one of an injection amount, an injection pressure, or an injection speed depending on their functions, but all the injection amount, the injection pressure, and the injection speed may be the same.

Here, when the first process station 111, the second process station 112, the third process station 113, and the fourth process station 114 are disposed in a clockwise direction, the supply of the first process gas may move in the clockwise direction in order of: the first process station 111→the second process station 112→the third process station 113→the fourth process station 114, and the supply of the second process gas, the first purge gas, and the second purge gas may also move in the clockwise direction along the arrangement direction of the first process station 111, the second process station 112, the third process station 113, and the fourth process station 114. When the first process station 111, the second process station 112, the third process station 113, and the fourth process station 114 are disposed in a counterclockwise direction, the supply of the first process gas may move in the counterclockwise direction in order of: the first process station 111→the second process station 112→the third process station 113→the fourth process station 114, and the supply of the second process gas, the first purge gas, and the second purge gas may also move in the counterclockwise direction along the arrangement direction of the first process station 111, the second process station 112, the third process station 113, and the fourth process station 114.

In each process, the arrangement direction of the process station(s) to which each of the first process gas, the first purge gas, the second process gas, and the second purge gas is supplied may be a direction opposite to the arrangement direction of the first process station 111, the second process station 112, the third process station 113, and the fourth process station 114. When the first process station 111, the second process station 112, the third process station 113, and the fourth process station 114 are arranged in the clockwise direction, the process station(s) to which each of the first process gas, the first purge gas, the second process gas, and the second purge gas is supplied may be arranged in the counterclockwise direction, and when the first process station 111, the second process station 112, the third process station 113, and the fourth process station 114 are arranged in the counterclockwise direction, the process station(s) to which each of the first process gas, the first purge gas, the second process gas, and the second purge gas is supplied may be arranged in the clockwise direction.

Here, the first process (S100) may include a process (S110) of supplying the first process gas, the second purge gas, the second process gas, and the first purge gas into the first process station 111, the second process station 112, the third process station 111, and the fourth process station 114, respectively, the second process (S200) may include a process (S210) of supplying the first purge gas, the first process gas, the second purge gas, and the second process gas into the first process station 111, the second process station 112, the third process station 113, and the fourth process station 114, respectively, the third process (S300) may include a process (S310) of supplying the second process gas, the first purge gas, the first process gas, and the second purge gas into the first process station 111, the second process station 112, the third process station 113 and the fourth process station 114, respectively, and the fourth process (S400) may include a process of supplying the second purge gas, the second process gas, the first purge gas, and the first process gas into the first process station 111, the second process station 112, the third process station 113, and the fourth process station 114, respectively.

The first process gas, the second purge gas, the second process gas, and the first purge gas may be supplied to the first process station 111, the second process station 112, the third process station 113, and the fourth process station 114, respectively (S110). The first process gas, the second purge gas, the second process gas, and the first purge gas may be supplied first to the first process station 111, the second process station 112, the third process station 113, and the fourth process station 114, respectively, and different gases may be supplied to the process stations, respectively.

In addition, the first purge gas, the first process gas, the second purge gas, and the second process gas may be supplied to the first process station 111, the second process station 112, the third process station 113, and the four process stations 114, respectively (S210). The first purge gas, the first process gas, the second purge gas, and the second process gas may be supplied to the first process station 111, the second process station 112, the third process station 113, and the fourth process station 114, respectively, and different gases may be supplied to the process stations, respectively.

Then, the second process gas, the first purge gas, the first process gas, and the second purge gas may be supplied to the first process station 111, the second process station 112, the third process station 113, and the fourth process station 114, respectively (S310). The second process gas, the first purge gas, the first process gas, and the second purge gas may be supplied to the first process station 111, the second process station 112, the third process station 113, and the fourth process station 114, respectively, and different gases may be supplied to the process stations, respectively.

In addition, the second purge gas, the second process gas, the first purge gas, and the first process gas may be supplied to the first process station 111, the second process station 112, the third process station 113, and the four process station 114, respectively (S410). The second purge gas, the second process gas, the first purge gas, and the first process gas may be supplied to the first process station 111, the second process station 112, the third process station 113, and the fourth process station 114, respectively, and different gases may be supplied to the process stations, respectively.

That is, the gases may be supplied to the first process station 111 in order of: the first process gas S→the first purge gas SP→the second process gas R→the second purge gas RP, may be supplied to the second process station 112 in order of: the second purge gas RP→the first process gas S→the first purge gas SP→the second process gas R, may be supplied to the third process station 113 in order of: the second process gas R→the second purge gas RP→the first process gas S→the first purge gas SP, and may be supplied to the fourth process station 114 in order of: the first purge gas SP→the second process gas R→the second purge gas RP→the first process.

Thus, since different gases are supplied to respective process stations at the same time, the amount and/or pressure of gas supplied between the first process station 111, the second process station 112, the third process station 113, and the fourth process station 114 may be controlled constantly to improve the thickness uniformity of the thin film deposited in each process station may be controlled to be constant, and thus, the thickness uniformity of the thin film deposited at each process station may be improved. That is, since each of the first process gas, the second process gas, the first purge gas, and the second purge gas are supplied (sequentially) to the process stations, the amount and pressure of each gas may be adjusted and reflected immediately. When the same gas is supplied at the same time to two or more process stations, the amount and/or pressure of the gas may be different between the two or more process stations, and even if the amount and pressure of the gas are adjusted, a reflection rate may vary for each process station, and also, the amount and pressure of the gas may not be adjusted well.

Therefore, in the substrate processing method in accordance with an exemplary embodiment, the first process gas, the second process gas, the first purge gas, and the second purge gas may be divided to be respectively supplied to the first process station 111, the second process station 112, the third process station 113, and the fourth process station 114 to sequentially supply the first process gas, the first purge gas, the second process gas, and the second purge gas into the respective process stations, and thus, different processes may be performed in the process stations, respectively. Therefore, a thin film having a uniform thickness may be deposited in each process station, and gas supply efficiency may be improved.

Here, the second process station 112 may be disposed in a first direction of the first process station 111, the fourth process station 114 may be disposed in a second direction perpendicular to the first direction of the first process station 111, and the third process station 113 may be disposed in a diagonal direction between the first direction and the second direction of the first process station 111. That is, the first process station 111 and the third process station 113 may be disposed in a diagonal direction with respect to each other, and the second process station 112 and the fourth process station 114 may be disposed in the diagonal direction with respect to each other. Here, when the first process gas and the second process gas are supplied to the first process station 111 and the third process station 113, respectively, the first purge gas and the second purge gas may be supplied to the second process station 112 and the fourth process station 114, respectively, and when the first process gas and the second process gas are supplied to the second process station 112 and the fourth process station 114, respectively, the first purge gas and the second purge gas may be supplied to the first process station 111 and the third process station 113, respectively.

In this case, each of the first purge gas and the second purge gas may function as an air curtain in the diagonal direction, (a space of) the process station to which the first process gas is supplied and (a space of) the process station to which the second process gas is supplied may be separated (or divided), and deposition may be performed independently of the process station, into which the first process gas is supplied, and the process station, into which the second process gas is supplied, without a mutual influence.

If the process station, to which the first process gas is supplied, and the process station, to which the second process gas is supplied (for example, the first process station and the third process station or the second process station and the fourth process station) are disposed (to be in contact with each other) in the first direction or the second direction, the process station, to which the first process gas is supplied, and the process station, to which the second process gas is supplied, may communicate with each other, and thus, the second process gas may affect the process station, to which the first process gas is supplied, and the first process gas may affect the process station, to which the second process gas is supplied.

However, as in the present disclosure, when the process station, to which the first process gas is supplied, and the process station, to which the second process gas is supplied, are disposed in the diagonal direction, the communication therebetween may be blocked by the first purge gas and the second purge gas of the process station, to which the first purge gas is supplied, and the process station, to which the second purge gas is supplied, to isolate (separate) the process station, to which the first process gas is supplied, from the process state, to which the second process gas is supplied.

Here, the first process gas and the second process gas may be different from the first purge gas and the second purge gas in at least one of an injection amount, an injection pressure, or an injection speed in the first process (S100), the second process (S200), the third process (S300), and the fourth process (S400). At least one of an injection amount (per unit time), an injection pressure, or an injection speed (or a movement speed of a gas) of each of the first process gas and the second process gas in the first process (S100), the second process (S200), the third process (S300), and the fourth process (S400) may be different from that of each of the first purge gas and the second purge gas, and thus, the first purge gas and the second purge gas may effectively perform the role of an air curtain while performing the role of the purge, and the first process gas and the second process gas may be effectively deposited on a substrate 10 without being affected by the first purge gas and the second purge gas.

For example, at least one of the injection amount, the injection pressure, or the injection speed of each of the first process gas and the second process gas may be different from that of each of the first purge gas and the second purge gas due to a difference in size between a first gas reservoir 121a, a second gas reservoir 122a, a first purge reservoir 123a, and a second purge reservoir 124a.

In addition, in the first process (S100), the second process (S200), the third process (S300), and the fourth process (S400), at least one of the injection amount, the injection pressure, or the injection speed of the first purge gas and the second purge gas may be the same. At least one of the injection amount, the injection pressure, or the injection speed of the first purge gas and the second purge gas in the first process (S100) may be the same, and thus, the air curtain through the first purge gas and the second purge gas may be formed along the diagonal direction. Therefore, a (process) pressure within each of the process station to which the first process gas is supplied and the process station to which the second process gas is supplied may be uniform overall, and the first process gas and the second process gas may be uniformly deposited on the entire surface of the substrate 10. For example, the first purge reservoir 121a and the second purge reservoir 122a may have the same size, and thus, at least one of the injection amount, the injection pressure, or the injection speed of the first purge gas and the second purge gas may be the same.

The first process (S100) to the fourth process (S400) may be one cycle, and the first process (S100) to the fourth process (S400) may be sequentially (or in the cycle) repeated depending on the required deposition thickness. Here, the substrate processing method according to an exemplary embodiment may further include a process (S450) of supplying the first purge gas and/or the second purge gas 112 to at least the second process station 112 and fourth process station 114 of the first process station 111, the second process station 112, the third process station 113, and the fourth process station 114.

The first purge gas and/or the second purge gas 112 may be supplied to at least the second process station 112 and fourth process station 114 of the first process station 111, the second process station 112, the third process station 113, and the fourth process station 114 (S450). After repeating the cycle by the necessary number of times n, the first purge gas and/or the second purge gas may be supplied to at least the second process station 112 and the fourth process state 114 of the first process station 111, the second process station 112, the third process station 113, and the fourth process station 114, and in the cycle, since respective processes are completed with the first process gas and the second process gas in the fourth process station 114 and the second process station 112, respectively, in the second process station 112 and the fourth process station 114, the purge of the second process gas and the purge of the first process gas may not be performed, and thus, a residual gas (water) of the second process gas and a residual gas (water) of the first process gas may remain. Thus, the first purge gas and/or the second purge gas may be supplied to at least the second process station 112 and the fourth process station 114 of the first process station 111, the second process station 112, the third process station 113, and the fourth process station 114, and thus, the residual gas of the second process gas may be removed from the second process station 112, and the residual gas of the first process gas may be removed from the fourth process station 114.

When supplying the first purge gas and/or the second purge gas only to the second process station 112 and the fourth process station 114, since the residual gas (water) of the second process gas and the residual gas (water) of the first process gas are spread to the first process station 111 and/or the third process station 113 due to a difference in pressure for each process station, the first purge gas and/or the second purge gas may be supplied to all of the first process station 111, the second process station 112, the third process station 113, and the fourth process station 114.

As described above, in the present disclosure, the plurality of gases may be divided to be respectively supplied to the first process station, the second process station, the third process station, and the fourth process station of the multi-station chamber so that the certain amount of gases is supplied always into the multi-station chamber. Therefore, the stable process pressure within the multi-station chamber may be controlled, and the contamination of the multi-station chamber due to the rapid change in process pressure within the multi-station chamber due to the change in gas may be improved. In addition, the amount and/or pressure of gas supplied between the first process station, the second process station, the third process station, and the fourth process station may be controlled constantly to improve the thickness uniformity of the thin film deposited in each process station. That is, the first process gas, the second process gas, the first purge gas, and the second purge gas may be divided to be respectively supplied to the first process station, the second process station, the third process station, and the fourth process station to sequentially supply the first process gas, the first purge gas, the second process gas, and the second purge gas into the respective process stations, and thus, each process station may perform a different process. Therefore, the thin film having the uniform thickness may be deposited in each process station, and the gas supply efficiency may be improved. In addition, the first process gas, the first purge gas, the second process gas, and the second purge gas may be sequentially supplied to perform the atomic layer deposition of the thin film, and the supply of each of the first process gas, the first purge gas, the second process gas, and the second purge gas may be controlled precisely so that the thin film is deposited uniformly at the atomic layer level on the entire surface of the substrate.

The substrate processing apparatus in accordance with the exemplary embodiments may separately supply the plurality of gases to the first process station, the second process station, the third process station, and the fourth process station of the multi-station chamber so that the certain amount of gases is supplied always into the multi-station chamber. Therefore, the stable process pressure within the multi-station chamber may be controlled, and the contamination of the multi-station chamber due to the rapid change in process pressure within the multi-station chamber due to the change in gas may be improved.

In addition, the amount and/or pressure of gas supplied between the first process station, the second process station, the third process station, and the fourth process station may be controlled constantly to improve the thickness uniformity of the thin film deposited in each process station.

That is, the different processes may be respectively performed in the process stations through the substrate processing method in which the first process gas, the second process gas, the first purge gas, and the second purge gas are divided to be respectively supplied to the first process station, the second process station, the third process station, and the fourth process station to sequentially supply the first process gas, the first purge gas, the second process gas, and the second purge gas into the respective process stations, and thus, the thin film having the uniform thickness may be deposited in each process station, and the gas supply efficiency may be improved.

In addition, the first process gas, the first purge gas, the second process gas, and the second purge gas may be sequentially supplied to perform the atomic layer deposition (ALD) of the thin film, and the supply of each of the first process gas, the first purge gas, the second process gas, and the second purge gas may be controlled stably and precisely so that the thin film is deposited uniformly at the atomic layer level on the entire surface of the substrate.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

What is claimed is:

1. A substrate processing apparatus comprising:
a multi-station chamber comprising a first process station, a second process station, a third process station, and a fourth process station, each of which independently performs processes, and configured to perform processes for a plurality of substrates;
a gas supply unit configured to divide a plurality of gases to respectively supply the plurality of gases to the first process station, the second process station, the third process station, and the fourth process station; and
a control unit configured to control the gas supply unit so that the plurality of gases are sequentially supplied to the first to fourth process stations by alternating the gases supplied between the first process station, the second process station, the third process station, and the fourth process station.

2. The substrate processing apparatus of claim 1, wherein the gas supply unit comprises:
a first gas supply part configured to supply a first process gas to the multi-station chamber;
a second gas supply part configured to supply a second process gas different from the first process gas to the multi-station chamber;
a first purge supply part configured to supply a first purge gas to the multi-station chamber; and
a second purge supply part configured to supply a second purge gas to the multi-station chamber.

3. The substrate processing apparatus of claim 2, wherein the control unit controls the first gas supply part, the second gas supply part, the first purge supply part, and the second purge supply part so that the first process gas, the second process gas, the first purge gas, and the second purge gas are divided to be respectively supplied to different process stations of the first process station, the second process station, the third process station, the third process station, and the fourth process station.

4. The substrate processing apparatus of claim 3, wherein the second process station is disposed in a first direction of the first process station,
the fourth process station is disposed in a second direction perpendicular to the first direction of the first process station, and
the third process station is disposed in a diagonal direction between the first direction and the second direction of the first process station.

5. The substrate processing apparatus of claim 4, wherein the control unit is configured to:
control the first gas supply part so that the first process gas is supplied in order of the first process station, the second process station, the third process station, and the fourth process station;
control the first purge supply part so that the first purge gas is supplied in order of the fourth process station, the first process station, the second process station, and the third process station;
control the second gas supply part so that the second process gas is supplied in order of the third process station, the fourth process station, the first process station, and the second process station; and
control the second purge supply part so that the second purge gas is supplied in order of the second process station, the third process station, the fourth process station, and the first process station.

6. The substrate processing apparatus of claim 2, wherein the first gas supply part comprises a first gas reservoir connected to each of the first process station, the second process station, the third process station, and the fourth process station and configured to store the first process gas so as to selectively supply the first process gas to the first process station, the second process station, the third process station, and the fourth process station,
the second gas supply part comprises a second gas reservoir connected to each of the first process station, the second process station, the third process station, and the fourth process station and configured to store the second process gas so as to selectively supply the second process gas to the first process station, the second process station, the third process station, and the fourth process station,
the first purge supply part comprises a first purge reservoir connected to each of the first process station, the second process station, the third process station, and the fourth process station and configured to store the first purge gas so as to selectively supply the first purge gas to the first process station, the second process station, the third process station, and the fourth process station, and
the second purge supply part comprises a second purge reservoir connected to each of the first process station, the second process station, the third process station, and the fourth process station and configured to store the second purge gas so as to selectively supply the second purge gas to the first process station, the second process station, the third process station, and the fourth process station.

7. The substrate processing apparatus of claim 6, wherein each of the first gas reservoir and the second gas reservoir has a size different from that of each of the first purge reservoir and the second purge reservoir.

8. The substrate processing apparatus of claim 7, wherein each of the first purge reservoir and the second purge reservoir has a size less than that of each of the first gas reservoir and the second gas reservoir.

9. The substrate processing apparatus of claim 6, wherein the first purge reservoir and the second purge reservoir have the same size.

10. The substrate processing apparatus of claim 6, wherein the first gas supply part further comprises a plurality of first gas valves provided between each of the first process station, the second process station, the third process station, and the fourth process station and the first gas reservoir,
the second gas supply part further comprises a plurality of second gas valves provided between each of the first process station, the second process station, the third process station, and the fourth process station and the second gas reservoir,
the first purge supply part further comprises a plurality of first purge valves provided between each of the first process station, the second process station, the third process station, and the fourth process station and the first purge reservoir, and
the second purge supply part further comprises a plurality of second purge valves provided between each of the first process station, the second process station, the third process station, and the fourth process station and the second purge reservoir.

11. The substrate processing apparatus of claim 10, further comprising a plurality of valve blocks on which the first gas valve, the second gas valve, the first purge valve, and the second purge valve are supported, respectively, and which are provided on upper portions of the first process station, the second process station, the third process station, and the fourth process station, respectively.

12. A substrate processing method using a multi-station chamber comprising a first process station, a second process station, a third process station, and a fourth process station, in which respective processes are independently performed, the substrate processing method comprising:
a first process of dividing a plurality of gases to primarily supply gases to the first process station, the second process station, the third process station, and the fourth process station, respectively;
a second process of dividing the plurality of gases to secondarily supply gases so that the gases different from the gases supplied in the first process are supplied to the first process station, the second process station, the third process station, and the fourth process station, respectively;
a third process of dividing the plurality of gases to tertiarily supply gases so that the gases different from the gases supplied in the second process are supplied to the first process station, the second process station, the third process station, and the fourth process station, respectively, and
a fourth process of dividing the plurality of gases to quaternarily supply gases so that the gases different from the gases supplied in the third process are supplied to the first process station, the second process station, the third process station, and the fourth process station, respectively.

13. The substrate processing method of claim 12, wherein the plurality of gases comprise a first process gas, a second process gas different from the first process gas, a first purge gas, and a second purge gas,
wherein the first process comprises a process of supplying the first process gas, the second purge gas, the second process gas, and the first purge gas to the first process station, the second process station, the third process station, and the fourth process station, respectively;
the second process comprises a process of supplying the first purge gas, the first process gas, the second purge gas, and the second process gas to the first process station, the second process station, the third process station, and the fourth process station, respectively;
the third process comprises a process of supplying the second process gas, the first purge gas, the first process gas, and the second purge gas to the first process station, the second process station, the third process station, and the fourth process station, respectively; and
the fourth process comprises a process of supplying the second purge gas, the second process gas, the first purge gas, and the first process gas to the first process station, the second process station, the third process station, and the fourth process station, respectively.

14. The substrate processing method of claim 13, wherein the second process station is disposed in a first direction of the first process station,
the fourth process station is disposed in a second direction perpendicular to the first direction of the first process station, and
the third process station is disposed in a diagonal direction between the first direction and the second direction of the first process station.

15. The substrate processing method of claim 14, wherein the first process gas and the second process gas are different from the first purge gas and the second purge gas in at least one of an injection amount, an injection pressure, or an injection speed in the first process, the second process, the third process, and the fourth process.

16. The substrate processing method of claim 14, wherein, in the first process, the second process, the third process, and the fourth process, at least one of the injection amount, the injection pressure, or the injection speed of the first purge gas and the second purge gas is the same.
